(19) United States
(12) Patent Application Publication
(10) Pub. No.: US 2021/0389368 A1
(43) Pub. Date: Dec. 16, 2021

(54) Design System For Test Adaptor Card And Method Thereof

(71) Applicants: Inventec (Pudong) Technology Corporation, Shanghai (CN); Inventec Corporation, Taipei City (TW)

(72) Inventors: Lin Zhang, Shanghai (CN); Qiu-Yue Duan, Shanghai (CN); Xiao-Xiao Mao, Shanghai (CN)

(21) Appl. No.: 16/905,785

(22) Filed: Jun. 18, 2020

(30) Foreign Application Priority Data
Jun. 15, 2020 (CN) 202010541849.5

(51) Int. Cl. G01R 31/28

(52) U.S. Cl. CPC G01R 31/2815; G01R 31/2808

(57) ABSTRACT

A design system for a test adapter card is provided. The circuitry to be tested on a motherboard is divided to form multiple modules to be tested, each of which corresponds to an interface to be tested. According to specifications of preset interfaces, the preset interface corresponding to each interface to be tested is selected, wherein the specifications of the preset interfaces conform to connector specifications of commercially available cables, multiple preset pins included in the selected preset interface completely cover the pins to be tested included in the corresponding interface to be tested, and the number of the preset pins included in the selected preset interface is greater than or equal to the number of the pins to be tested included in the corresponding interface to be tested. Design information required for producing the test adapter card is output based on the selection result and the division result.

### CROSS-REFERENCE TO RELATED APPLICATION

This application claims the benefit of Chinese Application Serial No. 202010541849.5, filed Jun. 15, 2020, which is hereby incorporated herein by reference in its entirety.

### BACKGROUND OF THE INVENTION

### 1. Field of the Invention

The present invention relates to a design system and a method thereof. In particular, the invention pertains to a design system for a test adapter card and a method thereof.

### 2. Description of the Related Art

Boundary scan testing has gradually developed into an important test method before a motherboard leaves the factory because of its advantages, such as high test coverage, short test time, and accurate fault location. At present, before the boundary scan testing is performed on a motherboard, it needs to design a test adapter card for all the non-standard interfaces of the motherboard to be tested to connect the motherboard to the standard boundary scan inspection (BSI) testing fixture.

For the design of the test adapter card, the production line maintenance personnel are required to be familiar with the original functional logic and design of the standard BSI testing fixture, in order to avoid the risk of exposure of the original functional logic and design of the standard BSI testing fixture. Therefore, only the internal R&D personnel can design the test adapter card so that it is difficult to outsource the design work of the test adapter card.

In addition, based on the interface design of the standard BSI testing fixture, if the standard BSI testing fixture directly connects to the test adapter card, there may be an assembling interference problem, and then the situation may occur where multiple interfaces may have the same pin sequence, but multiple adapter cards have to be designed. If the standard BSI testing fixture does not directly connect to the test adapter cards, it needs to use a variety of non-standard pin-to-pin cables to connect the test adapter card and the standard BSI testing fixture. However, customizing the non-standard pin-to-pin cable for the non-standard interfaces of the motherboards of various manufacturers has the problems of high price and restrictions on intellectual property rights. Therefore, it is really necessary to propose improved technical means to solve these problems.

### SUMMARY OF THE INVENTION

In order to solve the problems of the prior art, the present invention discloses a design system for a test adapter card and a method thereof.

First, the present invention discloses the design system for the test adapter card, which includes: a database, a receiving module, a dividing module, a selecting module and an output module. The dividing module connects to the receiving module, the selecting module connects to the dividing the module and the database, and the output module connects to the dividing module, the selecting module and the database. The database is configured to store specifications of a plurality of preset interfaces of a standard universal adapter card, wherein the standard universal adapter card connects to a standard BSI testing fixture, and the specifications of the plurality of preset interfaces conforms to connector specifications for commercially available cables. The receiving module is configured to receive a design layout of a motherboard to be tested. The dividing module is configured to divide circuitry be tested on the motherboard to be tested according to module categories based on the design layout of the motherboard to be tested to form a plurality modules to be tested, wherein each module to be tested corresponds to an interface to be tested, and each interface to be tested includes different types of pins to be tested. The selecting module is configured to select the preset interface corresponding to each interface to be tested according to the pins to be tested included in each interface to be tested and the specifications of the plurality of preset interfaces, wherein a plurality of preset pins included in the selected preset interface completely covers the pins to be tested included in the corresponding interface be tested, and the number of the preset pins included in the selected preset interface is greater than or equal to the number of the pins to be tested included in the corresponding interface be tested. The output module is configured to output design information required for producing the test adapter card corresponding to the motherboard to be tested based on a selection result of the selecting module and a division result of the dividing module.

In addition, the present invention discloses a test adapter card design method, which includes the following steps: storing specifications of a plurality of preset interfaces of a standard universal adapter card, wherein the standard universal adapter card is connected to a standard BSI testing fixture, the specifications of the plurality of preset interfaces conforms to connector specifications of commercially available cables; receiving a design layout of a motherboard to be tested; dividing circuitry to be tested on the motherboard to be tested to form a plurality of modules to be tested according to module categories based on the design layout of the motherboard to be tested, wherein each module to be tested corresponds to an interface to be tested, and each interface to be tested includes different types of pins to be tested; selecting the preset interface corresponding to each interface to be tested according to the pins to be tested included in each interface to be tested and the specifications of the plurality of preset interfaces, wherein a plurality of preset pins included in the selected preset interface completely covers the pins to be tested included in the corresponding interface be tested, and the number of the preset pins included in the selected preset interface is greater than or equal to the number of the pins to be tested included in the corresponding interface be tested; and outputting design information required for producing the test adapter card corresponding to the motherboard to be tested based on a selection result and a division result.

The system and method disclosed in the present invention are as above. The differences from the prior art are that the circuitry to be tested on a motherboard is divided to form multiple modules to be tested, each of which corresponds to an interface to be tested; according to specifications of preset interfaces, the preset interface corresponding to each interface to be tested is selected, wherein the specifications of the preset interfaces conform to connector specifications of commercially available cables, multiple preset pins included in the selected preset interface completely cover the pins to be tested included in the corresponding interface to be tested, and the number of the preset pins included in the selected preset interface is greater than or equal to the number of the pins to be tested included in the corresponding interface to be tested; and the design information required for producing the test adapter card is output based on the selection result and the division result.

By the above-mentioned technical solution, the present invention only needs to redesign the test adapter card for different motherboards to be tested based on the specifications of the plurality of preset interfaces of the standard universal adapter card (the specifications of the plurality of preset interfaces conforms to the connector specifications of the commercially available cables), so that the different motherboards to be tested can be connected to the standard BSI testing fixture through the designed test adapter card, the commercial cables and the standard universal adapter card, which can solve the problems of the prior art.

### BRIEF DESCRIPTION OF THE DRAWINGS

The structure, operating principle and effects of the present invention will be described in detail by way of various embodiments which are illustrated in the accompanying drawings.

FIG. 1 is a system block diagram of an embodiment of a design system for a test adapter card of the present invention.

FIG. 2 is a method flowchart of an embodiment of a design method executed by the design system of FIG. 1.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise”, “include” and “have”, and variations such as “comprises”, “comprising”, “includes”, “including”, “has” and “having” will be acknowledged to imply the inclusion of stated elements but not the exclusion of any other elements.

The nouns defined herein are explained before illustration of a design system for a test adapter card and a method thereof. A database, a receiving module, a dividing module, a selecting module and an output module included in the design system for the test adapter card disclosed in the present invention, can be implemented mainly by hardware, and can cooperate with software or firmware. The software or firmware used in the techniques presented in the embodiment of the present invention can be stored in a machine-readable storage medium such as ROM, RAM, disk storage medium, optical storage medium, and flash memory device, and can be performed by at least one general-purpose or dedicated programmable microprocessor. In actual implementation, the software or firmware stored in the machine-readable storage medium can be executed by the one or more general-purpose or special-purpose programmable microprocessors to generate the dividing module and selecting module of the present invention. The design method for the test adapter card disclosed in the present invention can be implemented in a combination of hardware and software and/or firmware, and can also be implemented in a centralized manner in a computer system or in a decentralized manner in which different components are spread in several computer systems interconnected.

Furthermore, the database, the receiving module, the dividing module, the selecting module and the output module of the present invention can transmit information and data to each other through a wireless or wired method, wherein the wireless method include the use of Bluetooth, Zigbee or WiFi.

In addition, the design system for the test adapter card and the method thereof disclosed in the present invention are to design the test adapter cards corresponding to different motherboards to be tested based on the design of a standard universal adapter card connected to a standard BSI testing fixture (i.e., specifications of the preset interfaces and the special interfaces of the standard universal adapter card) and the consideration of connecting the standard universal adapter card to the test adapter card with commercially available cables. Thus, the motherboard can be connected to a standard BSI testing fixture by using a designed test adapter card, commercially available cables, and a standard universal adapter card, thereby solving the problems of the prior art. In a embodiment, the standard universal adapter card does not need to be redesigned for different motherboards to be tested (that is, the standard universal adapter card is universal), the standard universal adapter card may include at least one interface for connecting with the standard BSI testing fixture, an interface for connecting to an external power supply, an interface for common ground with the motherboard to be tested (that is, the standard universal adapter card and the motherboard to be tested are common grounded), a plurality of preset interfaces and at least one special interface, and an additional joint test action group (JTAG) interface, which is configured to connect the JTAG interface of the motherboard to be tested, wherein the preset interface and the special interface are used to connect the test adapter card designed by the design system and the method thereof disclosed in the present invention. Based on the specifications of the preset interfaces and the special interfaces of the standard universal adapter card conform to the connector specifications of the commercially available cables and the technical means of the present invention, so that the designed test adapter card can be connected to the standard universal adapter card by the commercially available cables. The standard BSI testing fixture connected to the standard universal adapter card can correspond to multiple preset interfaces and/or the at least one special interface. It should be noted that when the standard universal adapter card connects to multiple standard BSI testing fixtures, each preset interface and each special interface can only correspond to one standard BSI testing fixture.

Furthermore, the test adapter card designed by the present invention can be directly connected to the interfaces to be tested on the motherboard to be tested, and can be connected to the preset interfaces of the standard universal adapter card by the commercially available cables, so the design information required for the test adapter card of the present invention includes the specifications of the interfaces to be tested directly connected to the test adapter card and the specifications of the preset interfaces and/or the special interface indirectly connected to the test adapter card.

The following will describe the implementation of the present invention in detail with reference to the drawings and examples, so as to fully understand and implement the implementation process of how the present invention uses technical means to solve technical problems and achieve technical efficacy.

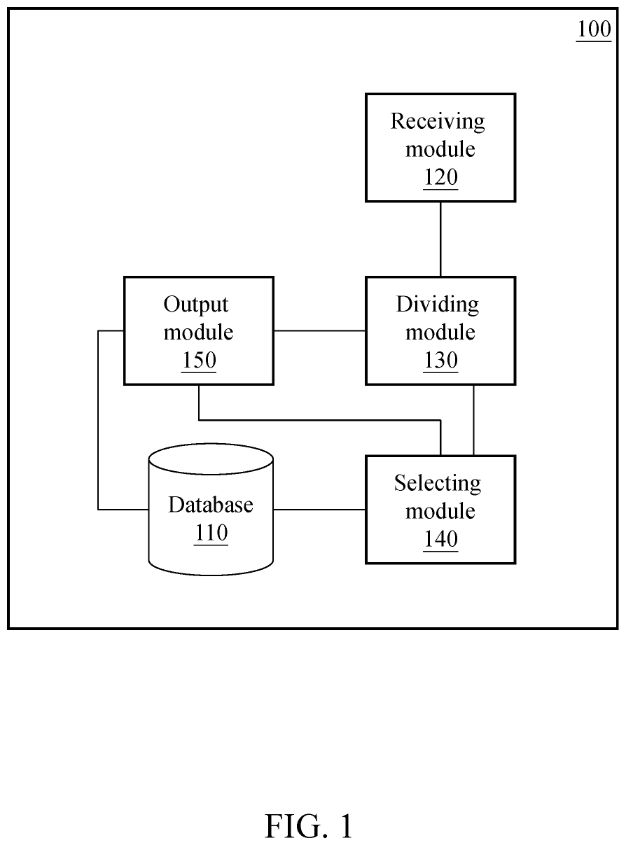

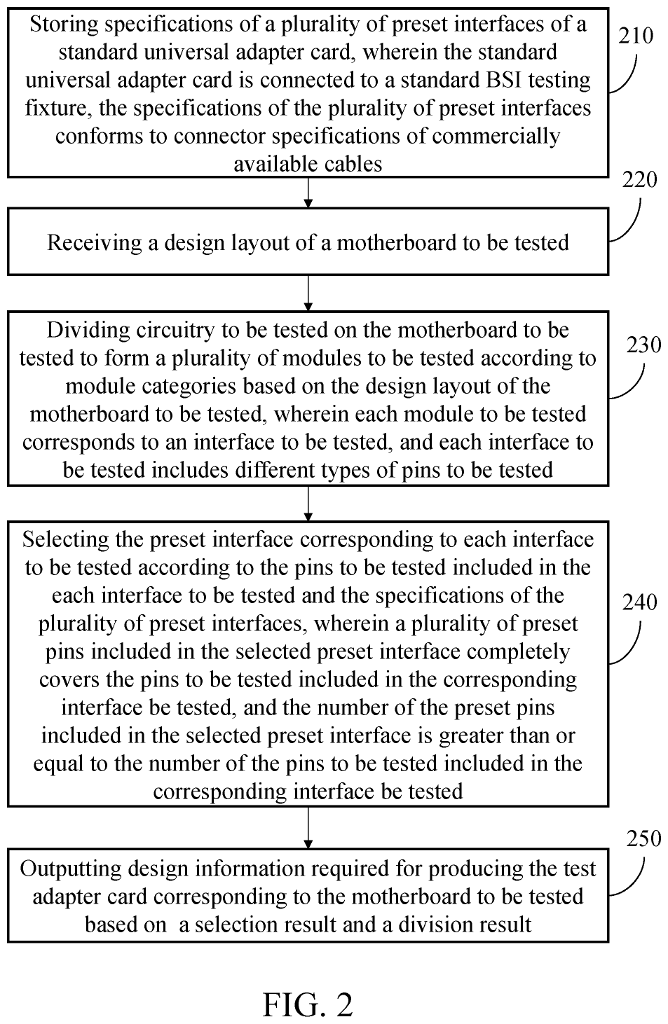

Please refer to FIG. 1 and FIG. 2, wherein FIG. 1 is a system block diagram of an embodiment of a design system for a test adapter card of the present invention, and FIG. 2 is a method flowchart of an embodiment of a design method executed by the design system of FIG. 1. In this embodiment, the design system 100 may include: a database 110, a receiving module 120, a dividing module 130, a selecting module 140, and an output module 150. The dividing module 130 can be connected to the receiving module 120, the selecting module 140 can be connected to the dividing module 130 and the database 110, and the output module 150 can be connected to the dividing module 130, the selecting module 140 and the database 110.

The design method performed by the design system 100 comprises the following steps: storing specifications of a plurality of preset interfaces of a standard universal adapter card, wherein the standard universal adapter card is connected to a standard BSI testing fixture, the specifications of the plurality of preset interfaces conforms to connector specifications of commercially available cables (step 210); receiving a design layout of a motherboard to be tested (step 220); dividing circuitry to be tested on the motherboard to be tested to form a plurality of modules to be tested according to module categories based on the design layout of the motherboard to be tested, wherein each module to be tested corresponds to an interface to be tested, and each interface to be tested includes different types of pins to be tested (step 230); selecting the preset interface corresponding to each interface to be tested according to the pins to be tested included in each interface to be tested and the specifications of the plurality of preset interfaces, wherein a plurality of preset pins included in the selected preset interface completely covers the pins to be tested included in the corresponding interface be tested, and the number of the preset pins included in the selected preset interface is greater than or equal to the number of the pins to be tested included in the corresponding interface be tested (step 240); and outputting design information required for producing the test adapter card corresponding to the motherboard to be tested based on a selection result and a division result (step 250).

In step 210, the design of the test adapter card needs to consider the design of the standard universal adapter card connected to the standard BSI testing fixture (that is, the specifications of the preset interfaces of the standard universal adapter card). Therefore, the database 110 can store the specifications of a plurality of preset interfaces of the standard universal adapter card. It should be noted that the specifications of these preset interfaces conforms to the connector specifications of commercially available cables, which means that each preset interface of the standard universal adapter card can connect to an external component, such as the test adapter card described in the invention, through the commercially available cables. The specification of each preset interface includes the type and the number of the preset pins of the preset interface. The type of the preset pin may be, but not limited to, a power pin, a ground pin, an input/output pin (I/O pin), a pull-up pin or a pull-down pin. For example, the specification of a certain preset interface stored in the database 110 includes five power pins, five ground pins, one I/O pin, zero pull-up pin, and one pull-down pin; the specification of another certain preset interface include two power pins, six ground pins, ten I/O pins, one pull-up pin, and one pull-down pin.

In step 220, since the design system 100 can design corresponding test adapter cards for different motherboards to be tested, the receiving module 120 can receive the design layout of any one motherboard to be tested to design the corresponding test adapter card for the any one motherboard to be tested through the follow-up steps.

In step 230, the dividing module 130 may divide the circuitry to be tested on the motherboard to be tested according to the module categories based on the design layout of the motherboard to be tested received by the receiving module 120 to form a plurality of modules to be tested, wherein each module to be tested may be, but not limited to, a power module (that is, a circuit that supplies power), a pull-up module (that is, a pull-up circuit, which is a circuit configured to clamp an uncertain signal to a high level through a resistor), a pull-down module (that is, a pull-down circuit, which is a circuit configured to clamp an uncertain signal to a low-level through a resistor) or an input and output module (that is, a circuit with logic operation and logic processing functions).

Each module to be tested corresponds to an interface to be tested, and each interface to be tested is configured to directly connect to the test adapter card designed according to the subsequent procedure, and each interface to be tested includes different types of pins to be tested (that is, each interface to be tested includes a plurality of pins to be tested), and the type of each pin to be tested may be, but not limited to, a power pin, a ground pin, a I/O pin, a pull-up pin, or a pull-down pin. When any one pin to be tested is a power pin, it means that it can be connected to a power circuit of the corresponding module to be tested; when any one pin to be tested is a ground pin, it means that it can be connected to a ground circuit of the corresponding module to be tested; when any one pin to be tested is a I/O pin, it means that it can be connected to a circuit with logic operation and logic processing function of the corresponding module to be tested; when any one pin to be tested is a pull-up pin, it means that it can be connected to a pull-up circuit of the corresponding module to be tested; and when any one pin to be tested is a pull-down pin, it means that it can be connected to a pull-down circuit of the corresponding module to be tested.

In step 240, the test adapter card designed by the present invention can connect the motherboard to be tested to the standard universal adapter card by the commercially available cables, so that the motherboard to be tested can connect to the standard BSI testing fixture through the designed test adapter card, the commercially available cables, and the standard universal adapter card. Therefore, the selecting module 140 needs to select the preset interfaces to which the test adapter card should be connected. In more detail, the selecting module 140 can select the preset interface corresponding to each interface to be tested according to the pins to be tested included in each interface to be tested and the specification of the preset interfaces, wherein the preset pins included in the selected preset interface completely cover the pins to be tested included in the corresponding interface to be tested (that is, the types and number of preset pins completely cover the types and number of pins to be tested. For example, when the pins to be tested included in the corresponding interface to be tested are one power supply pin, five ground pins, eight I/O pins, one pull-up pin and one pull-down pin, the preset pins included in the selected preset interface may be two power pins, six ground pins, ten I/O pins, one pull-up pin and one pull-down pin). The number of the preset pins included in the selected preset interface is greater than or equal to the number of the pins to be tested included in the corresponding interface to be tested. By the above method, when there is no interface to be tested with the special specification, the selecting module 140 can select the preset interface corresponding to each interface to be tested.

In step 250, the output module 150 may output the design information required for producing the test adapter card corresponding to the motherboard to be tested based on the selected preset interface corresponding to each interface to be tested (that is, the selection result of the selecting module 140) and the plurality of modules to be tested (that is, the division result of the dividing module 130). In more detail, the specifications of the interfaces to be tested directly connected to the test adapter card can be obtained by the dividing module 130 and the specifications of the preset interfaces indirectly connected to the test adapter card can be obtained by the selecting module 140 and the database 110, so the output module 150 can output the design information required to produce the test adapter card corresponding to the motherboard to be tested. It should be noted that the test adapter card can be designed as a combination of multiple first adapter cards according to actual requirements (for example, minimizing the size or avoiding assembling interference), wherein each first adapter card can correspond to one interface to be tested and/or one module to be tested.

Through the above steps, when there is no interface to be tested with the special specification, the design information required for the test adapter card can be obtained. However, each factory constantly develops its own interface model on the motherboard and constantly advances new technologies, so there may be such a situation where the interface to be tested is an interface with the special specification.

When a certain interface to be tested is an interface with the special specification, the selecting module 130 may not be able to select the preset pin corresponding to the certain interface to be tested according to the pins to be tested included in the certain interface to be tested and the specifications of the preset interfaces (that is, the types and number of the preset pins of any preset interface cannot completely cover the types and number of the pins to be tested of the certain interface to be tested). At this time, the special interfaces of the standard universal adapter card are considered to be used, wherein the special interfaces can conform to the connector specifications of the commercially available cables. In more detail, the database 110 can be further configured to store specification of at least one special interface of the standard universal adapter card, and the specification of the at least one special interface conforms to the connector specifications of the commercially available cables; the selecting module 140 can be configured to when there is a certain interface to be tested with the special specification, select the preset interface and the special interface corresponding to the certain interface to be tested according to the pins to be tested included in the certain interface to be tested, the specification of the at least one special interface, and the specifications of the plurality of preset interfaces, wherein the preset pins included in the selected preset interface and a plurality of special pins included in the selected special interface are to combine to completely cover the pins to be tested included in the certain interface to be tested (that is, the types and number of the selected preset pins and the types and number of the selected special pins completely cover the types and number of the pins to be tested of the certain interface to be tested). Therefore, the output module 150 can output the design information required to produce the test adapter card corresponding to the motherboard to be tested based on the selection result of the selecting module 140 and the division result of the division module 130.

In addition, before the boundary scan testing is performed on the motherboard to be tested, the motherboard to be tested may need to be processed to directly connect with the test adapter card designed by the present invention. Thus, in this embodiment, the output module 150 can be further configured to output processing information required by the motherboard to be tested on a boundary scan testing is performed according to the plurality of modules to be tested, the interface to be tested provided by each module to be tested, and the pins to be tested included in each interface to be tested, to provide relevant personnel to use the processing information to dispose the processing components, such as connectors, on the interfaces to be tested of the motherboard to be tested or to process the interfaces to be tested of the motherboard to be tested (for example, test pads are designed for the test through the thimble). The processing information required for the motherboard to be tested on the boundary scan testing is performed includes: the design information of the test pad or the connector required by each interface to be tested, and the design information of a pull-up circuit and/or a pull-down circuit required when any one module to be tested is a power module to be tested. To prevent excessive current, the pull-up circuit and/or the pull-down circuit need to be designed when the module to be tested is a power module.

In summary, the differences from the prior art are that the circuitry to be tested on a motherboard is divided to form multiple modules to be tested, each of which corresponds to an interface to be tested; according to specifications of preset interfaces, the preset interface corresponding to each interface to be tested is selected, wherein the specifications of the preset interfaces conform to connector specifications of commercially available cables, multiple preset pins included in the selected preset interface completely cover the pins to be tested included in the corresponding interface to be tested, and the number of the preset pins included in the selected preset interface is greater than or equal to the number of the pins to be tested included in the corresponding interface to be tested; and the design information required for producing the test adapter card is output based on the selection result and the division result. By the above-mentioned technical solution, the problems of the prior art can be solved, and the present invention only needs to redesign the test adapter card for different motherboards to be tested based on the specifications of the plurality of preset interfaces of the standard universal adapter card (the specifications of the plurality of preset interfaces conforms to the connector specifications of the commercially available cables), so that the different motherboards to be tested can be connected to the standard BSI testing fixture through the designed test adapter card, the commercial cables and the standard universal adapter card.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A design system for a test adapter card, comprising:
a database configured to store specifications of a plurality of preset interfaces of a standard universal adapter card, wherein the standard universal adapter card connects to a standard BSI testing fixture, and the specifications of the plurality of preset interfaces conforms to connector specifications for commercially available cables;
a receiving module configured to receive a design layout of a motherboard to be tested;
a dividing module connected to the receiving module, and configured to divide circuitry be tested on the motherboard to be tested according to module categories based on the design layout of the motherboard to be tested to form a plurality modules to be tested, wherein each module to be tested corresponds to an interface to be tested, and each interface to be tested includes different types of pins to be tested;
a selecting module connected to the dividing module and the database, and configured to select the preset interface corresponding to each interface to be tested according to the pins to be tested included in the each interface to be tested and the specifications of the plurality of preset interfaces, wherein a plurality of preset pins included in the selected preset interface completely covers the pins to be tested included in the corresponding interface be tested, and the number of the preset pins included in the selected preset interface is greater than or equal to the number of the pins to be tested included in the corresponding interface be tested; and
an output module connected to the dividing module, the selecting module and the database, and configured to output design information required for producing the test adapter card corresponding to the motherboard to be tested based on a selection result of the selecting module and a division result of the dividing module.

2. The design system for the test adapter card according to claim 1, wherein the database is further configured to store specification of at least one special interface of the standard universal adapter card, and the specification of the at least one special interface conforms to the connector specifications of the commercially available cables; and when the preset interface corresponding to a certain interface to be tested is not selected according to the pins to be tested included in the certain interface to be tested and the specifications of the plurality of preset interfaces, the selecting module is further configured to select the preset interface and the special interface corresponding to the certain interface to be tested according to the pins to be tested included in the certain interface to be tested, the specification of the at least one special interface, and the specifications of the plurality of preset interfaces, wherein the plurality of preset pins included in the selected preset interface and a plurality of special pins included in the selected special interface are to combine to completely cover the pins to be tested included in the certain interface to be tested.

3. The design system for the test adapter card according to claim 1, wherein the output module is further configured to output processing information required by the motherboard to be tested on a boundary scan testing is performed according to the plurality of modules to be tested, the interface to be tested provided by each module to be tested, and the pins to be tested included in each interface to be tested.

4. The design system for the test adapter card according to claim 3, wherein the processing information required by the motherboard to be tested on the boundary scan testing is performed includes: design information of a test pad or a connector required by each interface to be tested, and design information of a pull-up circuit and/or a pull-down circuit required when any one module to be tested is a power module to be tested.

5. A design method for a test adapter card, which comprising following steps:
storing specifications of a plurality of preset interfaces of a standard universal adapter card, wherein the standard universal adapter card is connected to a standard BSI testing fixture, the specifications of the plurality of preset interfaces conforms to connector specifications of commercially available cables;
receiving a design layout of a motherboard to be tested;
dividing circuitry to be tested on the motherboard to be tested to form a plurality of modules to be tested according to module categories based on the design layout of the motherboard to be tested, wherein each module to be tested corresponds to an interface to be tested, and each interface to be tested includes different types of pins to be tested;
selecting the preset interface corresponding to each interface to be tested according to the pins to be tested included in the each interface to be tested and the specifications of the plurality of preset interfaces, wherein a plurality of preset pins included in the selected preset interface completely covers the pins to be tested included in the corresponding interface be tested, and the number of the preset pins included in the selected preset interface is greater than or equal to the number of the pins to be tested included in the corresponding interface be tested; and
outputting design information required for producing the test adapter card corresponding to the motherboard to be tested based on a selection result and a division result.

6. The design method for the test adapter card according to claim 5, wherein the design method for the test adapter card further comprising the following steps:
storing specification of at least one special interface of the standard universal adapter card, and the specification of the at least one special interface conforms to the connector specifications of the commercially available cables; and
when the preset interface corresponding to a certain interface to be tested not being selected according to the pins to be tested included in the certain interface to be tested and the specifications of the plurality of preset interfaces, selecting the preset interface and the special interface corresponding to the certain interface to be tested according to the pins to be tested included in the certain interface to be tested, the specification of the at least one special interface, and the specifications of the plurality of preset interfaces, wherein the plurality of preset pins included in the selected preset interface and a plurality of special pins included in the selected special interface are to combine to completely cover the pins to be tested included in the certain interface to be tested.

7. The design method for the test adapter card according to claim 5, wherein the design method for the test adapter card further comprising the following steps: outputting processing information required by the motherboard to be tested on a boundary scan testing is performed according to the plurality of modules to be tested, the interface to be tested provided by each module to be tested, and the pins to be tested included in each interface to be tested.

8. The design method for the test adapter card according to claim 7, wherein the processing information required by the motherboard to be tested on the boundary scan testing is performed includes: design information of a test pad or a connector required by each interface to be tested, and design information of a pull-up circuit and/or a pull-down circuit required when any one module to be tested is a power module to be tested.
